(19) United States
(12) Patent Application Publication
(10) Pub. No.: US 2017/0276932 A1
(43) Pub. Date: Sep. 28, 2017

(54) OPTICAL ELEMENT MODULE AND METHOD FOR PRODUCING OPTICAL ELEMENT MODULE

(71) Applicant: Fujikura Ltd., Tokyo (JP)

(72) Inventor: Koichiro Iwata, Sakura-shi (JP)

(73) Assignee: Fujikura Ltd., Tokyo (JP)

(21) Appl. No.: 15/508,596

(22) PCT Filed: May 10, 2016
(86) PCT No.: PCT/JP2016/063897

§ 371 Date: Mar. 3, 2017

(30) Foreign Application Priority Data
Aug. 21, 2015 (JP) 2015-164197

(51) Int. Cl. G02B 27/00; H01L 31/0203; H01S 5/022; H01L 33/48

(52) U.S. Cl. CPC G02B 27/0006; H01L 33/483; H01L 31/0203; H01S 5/0222; H01S 5/02204

(57) ABSTRACT

An optical element module which can adsorb a foreign matter and absorb moisture remaining in the module with use of a simple structure which does not require a complicated production process is provided. An optical element module (101) includes a sealed housing (11, 12) and an optical element 1 mounted in the sealed housing (11, 12), said optical element module (101) further including polyurethane (13) having self-adherence and a desired shape, the polyurethane (13) being fixed inside said optical element module (101) with use of the self-adherence of the polyurethane (13).

### TECHNICAL FIELD

The present invention relates to an optical element module in which an optical element is mounted in a sealed housing, and a method for producing the optical element module.

### BACKGROUND ART

In general, an optical element module (hereinafter referred to as module) in which an optical element (element having an optical function; LD (Laser Diode) or LED (Light-emitting Diode)) is mounted in a sealed housing includes the housing, the optical element mounted in the housing, and a lid having a window which transmits light, and a dried inert gas is contained in the module.

Such a module suffers a problem that a foreign matter (of approximately 15 μm in diameter) and water mixed in the module have an adverse influence on the optical element. For example, if the foreign matter is present on an optical path of light incident to or emitted from the optical element, the foreign matter prevents the optical element from exerting a desired function.

In order to deal with this problem, Patent Literature 1 discloses a technique in which an adhesive layer is formed on an inner wall of a housing so that a foreign matter is adsorbed to the adhesive layer after sealing.

Patent Literature 2 discloses a technique in which a silica gel is mixed in an adhesive for fixing an optical element to a housing so that the silica gel absorbs moisture in a module.

### CITATION LIST

### Patent Literature

[Patent Literature 1]

Japanese Patent Application Publication Tokukai No. 2003-37256 (Publication date: Feb. 7, 2003)
[Patent Literature 2]

Japanese Patent Application Publication Tokukaihei No. 10-48242 (Publication date: Feb. 20, 1998)

### SUMMARY OF INVENTION

### Technical Problem

However, in the modules disclosed in Patent Literatures 1 and 2, the material for the adhesive layer or the adhesive is a liquid resin, and so the step of applying or spraying the liquid resin to the housing or the optical element is required. Consequently, the modules disclosed in Patent Literatures 1 and 2 suffer problems below.

First, Patent Literature 1 describes that when the adhesive layer is formed, an adhesive must not be attached to a light-receiving surface of a solid imaging element mounted in the housing, a transparent lid etc. This indicates that the technique disclosed in Patent Literature 1 requires the step of applying and curing the adhesive after mounting of the optical element and before sealing the housing. Accordingly, the technique disclosed in Patent Literature 1 requires a complicated production process.

Second, it is important to provide the module with a function of absorbing moisture. In order that the liquid resin has a volume necessary for absorbing moisture, the resin is required to be applied thickly. Consequently, the techniques disclosed in Patent Literatures 1 and 2 face high difficulty in production also in terms of controlling a thickness of the resin.

In the technique disclosed in Patent Literature 2, a silica gel is mixed with the adhesive so as to absorb moisture in the module. Consequently, the technique disclosed in Patent Literature 2 further suffers additional problems below.
(1) As a material for the adhesive with which a silica gel is mixed, a silicone resin with high moisture permeability which allows moisture to easily go to the silica gel is recommended. In general, the silicone resin is known to be likely to outgas siloxane etc. This may have an adverse influence on an optical element sealed in a housing.
(2) Assume that the adhesive with which the silica gel is mixed is not only used for fixing the optical element but also applied on an inner wall of the housing etc. so that the adhesive have a volume required for absorbing moisture. In that case, it is concerned that there might be a possibility that when the adhesive is cured, a part of silica gel particles remains on a surface of the adhesive and the part moves after the housing is sealed.

The present invention was made in view of the foregoing problems. An object of an aspect of the present invention is to provide an optical element module which can adsorb a foreign matter and absorb moisture remaining in the module with use of a simple structure which does not require a complicated production process, and a method for producing the optical element module.

### Solution to Problem

In order to solve the foregoing problems, an optical element module of an aspect of the present invention is an optical element module including a sealed housing and an optical element mounted in the sealed housing, said optical element module further including a resin molded article having self-adherence and a desired shape, the resin molded article being fixed inside said optical element module with use of the self-adherence of the resin molded article.

According to the above optical element module, the resin molded article having a desired shape itself has adherence (self-adherence). Accordingly, with use of the self-adherence, it is possible to easily fix the resin molded article inside the optical element module, e.g. fix the resin molded article to an inner wall of the housing or a surface of the optical element provision of the resin molded article on which surface would not block an optical path. This allows simplifying a production process for providing, in the optical element module, an element for adsorbing a foreign matter remaining inside the optical element module. Furthermore, since the resin molded article can be molded to have a desired shape beforehand, it is easy to cause the resin molded article to have a volume necessary for absorbing moisture remaining inside the optical element module.

A method of an aspect of the present invention for producing an optical element module is a method for producing an optical element module including a sealed housing and an optical element mounted in the sealed housing, said method comprising the steps of: attaching a resin molded article having self-adherence and a desired shape to at least the housing with use of the self-adherence of the resin molded article; vacuum-heating the housing on which the optical element has been mounted and to which the resin molded article has been attached; and thereafter attaching a lid with an optically transmissive section for transmitting light to the housing and sealing the housing and the lid.

According to the above method, in addition to the aforementioned simplification of the production process of the optical element module, it is also possible to reduce moisture remaining inside the optical element module as small as possible because the step of sealing is carried out after the step of vacuum-heating.

A method of an aspect of the present invention for producing an optical element module is a method for producing an optical element module including a sealed housing and an optical element mounted in the sealed housing, the optical element module further including a lid with an optically transmissive section for transmitting light, said method comprising the steps of: attaching a resin molded article having self-adherence and a desired shape to a portion in the housing which portion is near a portion at which the housing and the lid are to be sealed; and sealing the housing to which the resin molded article have been attached and the lid.

According to the above method, in the step of attaching the resin molded article, the resin molded article is attached to the portion near the portion at which the housing and the lid are to be sealed. Accordingly, the resin molded article can effectively adsorb a foreign matter entering the main body in the step of sealing.

### Advantageous Effects of Invention

The optical element module of an aspect of the present invention yields an effect of adsorbing a foreign matter and absorbing moisture remaining in the module with use of a simple structure which does not require a complicated production process.

### BRIEF DESCRIPTION OF DRAWINGS

FIG. 1 is a cross-sectional drawing schematically illustrating a configuration of an optical element module in accordance with Embodiment 1.

FIG. 2 is a cross-sectional drawing schematically illustrating a configuration of an optical element module in accordance with Embodiment 2.

FIG. 3 is a cross-sectional drawing schematically illustrating a configuration of another optical element module in accordance with Embodiment 2.

FIG. 4 is a cross-sectional drawing schematically illustrating a configuration of an optical element module in accordance with Embodiment 3.

FIG. 5 is a cross-sectional drawing schematically illustrating a configuration of another optical element module in accordance with Embodiment 3.

### DESCRIPTION OF EMBODIMENTS

### Embodiment 1

The following description will discuss embodiments of the present invention in details.

### (Schematic Description of Optical Element Module 101)

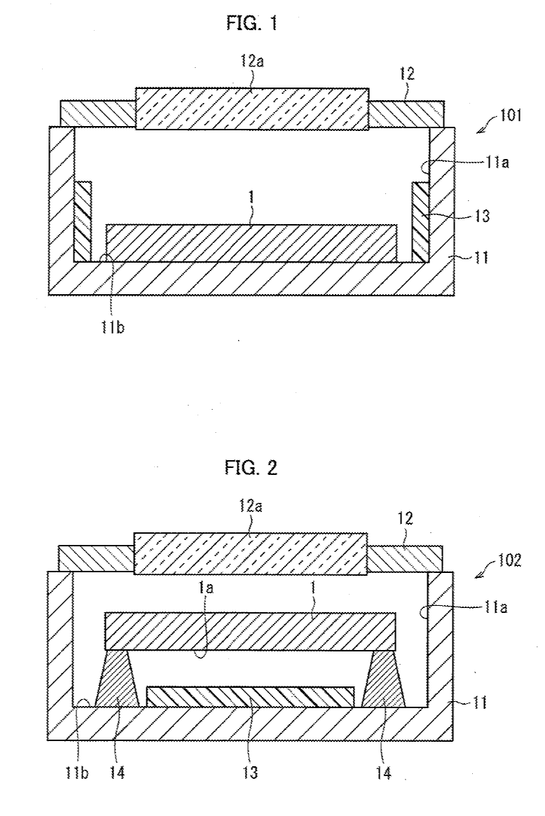

FIG. 1 is a cross-sectional drawing schematically illustrating a configuration of an optical element module 101 in accordance with Embodiment 1.

As illustrated in FIG. 1, the optical element module 101 includes a package main body (housing) 11 made of a metal, an optical element (element having an optical function) 1 on a bottom surface 11b of the package main body 11, and a lid 12 for sealing an opening of the package main body 11 so that the optical element 1 is sealed in the package main body 11.

As the optical element 1, an element having an optical function such as a reflecting function, a light-receiving function, or a light-emitting function is used. In Embodiment 1, the optical element 1 is an LCOS (Liquid Crystal On Silicon) which is a reflecting element (reflective optical switching element). It should be noted that the optical element 1 is not limited to this. For example, the optical element 1 may be other type of the reflecting element such as a MENS (Micro Electro Mechanical System) element, or may be a light-emitting element such as a laser diode, or may be a light-receiving element such as a photodiode.

A window 12a made of a transparent optical material is provided near a center of the lid 12. The window 12a transmits light emitted from the optical element 1 mounted in the package main body 11 toward the outside, and transmits light from the outside into the package main body 11.

A sheet polyurethane (resin molded article having adherence and a predetermined shape) 13 is attached to an inner side surface 11a of the package main body 11 so as to surround a part of, more preferably a whole of, the optical element 1 mounted on the bottom surface 11b of the package main body 11.

The polyurethane 13 adsorbs a foreign matter remaining inside the package main body 11. Polyurethane which is a resin material for a resin molded article is the most preferable example because polyurethane allows the resin molded article itself to have adherence (self-adherence) without requiring application of an adhesive etc., can be molded into a desired shape, and is relatively easy to absorb moisture. However, the resin material for the resin molded article is not limited to polyurethane. Any resin material which at least allows the resin molded article itself to have self-adherence and can be molded into a desired shape is applicable to the optical element module 101. An example of such a resin material for the resin molded article is an ethylene-vinyl acetate copolymer resin. Examples of the foreign matter above include fine metal particles and resin particles coming from a production device of the optical element module 101, fine fragments of the material, and dusts floating in the air.

### (Method for Producing Optical Element Module 101)

Initially, the optical element 1 is mounted on the bottom surface 11b of the package main body 11, and the polyurethane 13 is attached to the inner side surface 11 a so as to surround a part of or a whole of the optical element 1. That is, the package main body 11 is provided with the polyurethane 13 (molded article-attaching step).

Then, in order to sufficiently dry the polyurethane 13, the package main body 11 provided with the polyurethane 13 is vacuum-heated in a vacuum-heating step (drying step). Then, while the polyurethane 13 is kept in a dried state, i.e. without taking out the package main body 11 provided with the polyurethane 13 from a drying atmosphere, the lid 12 with the window 12a is put on the opening of the package main body 11 so that the package main body 11 is sealed (sealing step). In the sealing step, an inert gas such as dried nitrogen is injected into the package main body 11.

As a result, even if oxygen remains inside the optical element module 101, it is possible to reduce an amount of the remaining oxygen, so that it is possible to reduce inconvenience caused by the remaining oxygen, e.g. an adverse influence on the resin molded article. In particular, since there is a concern that oxygen deteriorates polyurethane, the amount of the oxygen in the optical element module 101 is required to be as small as possible.

The optical element module 101 illustrated in FIG. 1 is produced through the aforementioned steps.

In the drying step, heating is performed, for example, in a vacuumed state at 100° C. for 8 hours. Conditions of vacuum-heating are set so that remaining oxygen concentration for the optical element 1 (device) can be no greater than an acceptable value and there is no adverse influence on a function of the optical element 1. Furthermore, heating conditions are set after determining the amount and the shape of the polyurethane 13 to be provided inside the optical element module 1. A heating time will be sufficient by being determined in such a manner that a change in weight of the polyurethane 13 with time is measured, a time required for a decrease in weight of the polyurethane 13 to be stopped, i.e. a time required for obtaining a sufficient degree of dryness is determined based on the measurement, and the heating time is determined based on the time required for obtaining a sufficient degree of dryness. An inert gas atmosphere is maintained from the vacuum-heating step until the sealing step which is a subsequent step. It should be noted that a dew point at the vacuum-heating step is kept to be lower than a dew point at the sealing step.

In the sealing step, sealing is performed by joining the package main body 11 and the lid 12 via seam welding while a nitrogen gas whose dew point is set to −40° C. or less is contained in the package main body 11. In this embodiment, the package main body 11 is joined with the lid 12 via seam welding. Alternatively, projection welding may be employed. A gas to be contained in the package main body 11 is desirably an inert gas because if the gas includes oxygen, then deterioration in the polyurethane 13 would be accelerated. A suitable example of the gas is a nitrogen gas. The gas to be contained in the package main body 11 may include approximately 1-20% by volume of helium for the purpose of carrying out a leak test after the sealing step. The inert gas in this case is a mixture gas of nitrogen and helium, and helium occupies 1-20% by volume of the mixture gas.

The dew point of the gas contained in the optical element module 101 is suitably determined to be no greater than 0° C., no greater than −40° C. or the like depending on a temperature of a use environment supported from intended use of the optical element 1 mounted inside the package main body 11 or on a temperature of an environment in which the optical element module 101 is stored. In either environment, the dew point is desirably determined so that the gas does not make condensation.

That is, the dew point of the inert gas to be contained is preferably no greater than the lower one of the temperature of the use environment (use environment temperature) and the temperature at which the optical element module 101 is stored (storing temperature). The use environment temperature is a temperature at which the optical element module 101 is usable, and is determined to be 0° C. to 70° C. for example, and the storing temperature is a temperature at which the optical element module 101 is storable, and is determined to be −40° C. to 85° C. for example. In this example, the dew point of the inert gas is preferably determined to be no greater than −40° C. in accordance with the storing temperature which is lower. As described above, the dew point of the inert gas to be contained in the optical element module 101 is determined to be no greater than the lower one of the use environment temperature and the storing temperature. Such a dew point prevents the inert gas from making condensation inside the optical element module 101, thereby removing an adverse influence of moisture on the optical element 1 and the polyurethane 13.

### (Effect)

According to the optical element module 101 illustrated in FIG. 1, polyurethane is easy to be molded into a desired shape, and the polyurethane 13 itself having been molded into a desired shape has adherence (self-adherence). Accordingly, with use of this self-adherence, the polyurethane 13 can be easily fixed inside the optical element module 101 merely by attaching the polyurethane 13 to, for example, an inner wall of the housing or, as described later, a surface of the optical element 1 provision of the polyurethane 13 on which surface would not block an optical path. This allows simplifying a production process for providing the polyurethane 13 inside the optical element module 101. Furthermore, since the polyurethane 13 can be molded to have a desired shape beforehand, it is easy to cause the polyurethane 13 to have a volume necessary for absorbing moisture remaining inside the optical element module 101.

Furthermore, even if a foreign matter which cannot have been sufficiently removed before the sealing in the production process remains inside the package main body 11, it is possible to cause the remaining foreign matter to contact the polyurethane 13 and be adsorbed by the polyurethane 13 by giving a motion such as vibration to the package main body 11. Therefore, it is possible to subdue an inconvenience that the foreign matter enters an incident optical path to the optical element 1 or an emission optical path from the optical element 1 in the package main body 11 and the optical element 1 cannot exert a desired function.

Furthermore, even if air-tightness is lost in the optical element module 101 and moisture enters the optical element module 101, the polyurethane 13 absorbs the moisture. Accordingly, it is possible to mitigate an increase in dew point inside the package main body 11.

As described above, the optical element module 101 free from the adverse influence of the foreign matter remaining inside the package main body 11 can be provided by a simpler production process compared to the prior art.

In order to absorb a foreign matter or moisture remaining inside the package main body 11, the present invention is not limited to a configuration in which the polyurethane 13 in a continuous sheet form is attached to the inner side surface 11 a of the package main body 11 so as to extend fully along the inner side surface 11a as illustrated in FIG. 1. Alternatively, the polyurethane 13 in a short sheet form may be intermittently attached to the inner side surface 11a.

Alternatively, instead of the polyurethane 13 in a sheet form or in addition to the polyurethane 13 in a sheet form, the polyurethane 13 in a block form may be attached to the inner side surface 11a and/or the bottom surface 11b of the package main body 11, provided that attachment of the polyurethane 13 in a block form does not form an obstacle inside the package main body 11.

By the way, the polyurethane 13 deteriorates due to light, ultraviolet ray in particular. Accordingly, inside the package main body 11, the polyurethane 13 is preferably attached to a portion directly irradiated with light as small as possible. Embodiment 2 below will discuss an example in which the polyurethane 13 is attached to a portion which is not directly irradiated with light.

### Embodiment 2

The following description will discuss another embodiment of the present invention. Members having the same functions as those in Embodiment 1 are given the same reference signs and detailed explanations thereof are omitted.

### (Schematic Description on Optical Element Module 102)

FIG. 2 is a cross-sectional drawing schematically illustrating a configuration of an optical element module 102 in accordance with Embodiment 2.

The optical element module 102 illustrated in FIG. 2 is different from the optical element module 101 in Embodiment 1 on the two points below. Specifically, a first difference is that an optical element 1 (element having an optical function) is mounted above a bottom surface 11b of a package main body 11 via seats 14. A second difference is that polyurethane 13 is attached to the bottom surface 11b of the package main body 11 which bottom surface 11b faces a rear surface 1a of the optical element 1.

The seats 14 are each a member which contacts the rear surface 1a of the optical element 1 so that the optical element 1 is positioned by a predetermined distance above the bottom surface 11b of the package main body 11. In Embodiment 2, three seats 14 are provided, and the optical element 1 is supported at three points. The number of the seats 3 is not limited to three, and may be four or more. Alternatively, two seats 14 may be provided on the bottom surface 11b so as to face each other as illustrated in FIG. 2, provided that the two seats 14 each have a sufficient length to contact the rear surface 1a.

A height of each of the seats 14 should be determined so that the height can secure a space where the polyurethane 13 is provided below the rear surface 1a of the optical element 1 and the polyurethane 13 can adsorb a foreign matter.

In the optical element module 102 with the above configuration, the polyurethane 13 is attached to the bottom surface 11b of the package main body 11 so as to face the rear surface 1a of the optical element 1. Accordingly, the larger the area of the rear surface 1a of the optical element 1 is, the larger the area of the polyurethane 13 shielded from light is, so that the polyurethane 13 can be attached with a larger area. By securing a larger surface area and volume of the polyurethane 13, it is possible to secure a larger area to adsorb a foreign matter and a larger volume to absorb moisture.

Besides, the polyurethane 13 is attached to a position to which external light, i.e. light incident via a window 12a of a lid 12 does not reach because the light is blocked by the optical element 1. That is, the polyurethane 13 is attached to a position in the optical element module 101 which is not directly irradiated with light having passed through the window 12a serving as a light-transmitting section of the lid 12. Specifically, as illustrated in FIG. 2, the polyurethane 13 is attached to a portion of the bottom surface 11b in the package main body 11 which portion faces the optical element 1. This allows preventing the polyurethane 13 from being directly irradiated with the external light, thereby subduing deterioration of the polyurethane 13.

### (Schematic Description on Optical Element Module 103)

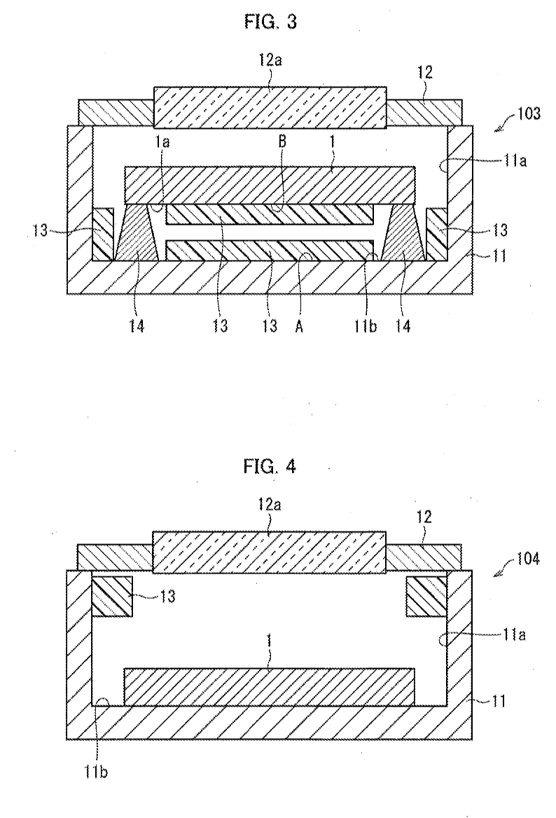

FIG. 3 is a cross-sectional drawing schematically illustrating a configuration of an optical element module 103 which is another optical element module in accordance with Embodiment 2.

As illustrated in FIG. 3, the optical element module 103 has more number of portions to which the polyurethane 13 is attached, compared to the configuration of the optical element module 102 illustrated in FIG. 2. Specifically, the polyurethane 13 is attached not to one of a position of the bottom surface 11b of the package main body 11 which position faces the optical element 1 (portion A) and a surface of the rear surface la of the optical element 1 which surface faces the bottom surface 11b of the package main body 11 (portion B), but to both of the portions A and B. Furthermore, the polyurethane 13 may be also attached to a position of the inner side surface 11a of the package main body 11 which position is not directly irradiated with external light having passed through the window 12a, so that the polyurethane 13 at that position surrounds the optical element 1.

The position to which the polyurethane 13 is attached is not limited to the position illustrated in FIG. 3. The polyurethane 13 may be attached to any position in the package main body 11 provided that the position is not directly irradiated with external light having passed through the window 12a. The polyurethane 13 may be attached to, other than the rear surface of the optical element 1, a side wall of a sub-mount (not illustrated) on which the optical element 1 is mounted, a rear surface of the lid 12 other than the window 12a, etc.

### (Effect)

The optical element module 103 with the above configuration can secure a larger surface area and a larger volume of the polyurethane 13 as compared to the optical element module 102 illustrated in FIG. 2, and accordingly can adsorb more number of foreign matters and more amount of moisture.

### (Supplemental Note)

In a case where the optical element module 102 illustrated in FIG. 2 or the optical element module 103 illustrated in FIG. 3 includes the optical element 1 which emits heat and/or a sub-mount which contains a heating element therein, a convective flow occurs in a space inside the optical element module 103 due to heat. This makes it easy for foreign matters such as fine particles floating inside the package main body 11 to move, so that the polyurethane 13 can adsorb the foreign matters efficiently.

By the way, in the step of seam-welding the lid 12 to the package main body 11, a foreign matter is easy to enter the package main body 11. Embodiment 3 below will discuss an example in which a foreign matter having entered the package main body 11 in the step of seam-welding the lid 12 to the package main body 11 is adsorbed effectively.

### Embodiment 3

The following description will discuss further another embodiment of the present invention. Members having the same functions as those in Embodiments 1 and 2 are given the same reference signs and detailed explanations thereof are omitted.

### (Schematic Description on Optical Element Module 104)

FIG. 4 is a cross-sectional drawing schematically illustrating a configuration of an optical element module 104 in accordance with Embodiment 3.

The optical element module 104 illustrated in FIG. 4 is different from the optical element module 101 in accordance with Embodiment 1 on the point below. Specifically, the difference is that polyurethane 13 is attached to a portion of an inner side surface 11a of the package main body 11 which portion is near a welded portion of the lid 12. In terms of efficiency in adsorbing a foreign matter, the polyurethane 13 is preferably attached to the inner side surface 11a of the package main body 11 so as to extend fully along the inner side surface 11a. Attaching the polyurethane 13 in such a way is also preferable in terms of absorption of moisture because it secures a larger volume of the polyurethane 13.

### (Schematic Description of Optical Element Module 105)

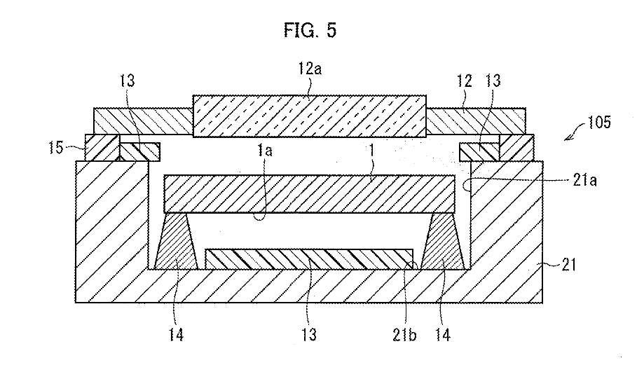

FIG. 5 is a cross-sectional drawing schematically illustrating a configuration of an optical element module 105 which is another optical element module in accordance with Embodiment 3.

The optical element module 105 illustrated in FIG. 5 is different from the optical element module 102 in accordance with Embodiment 2 above on the three points below. Specifically, a first difference is that a package main body 21 made of ceramics is employed instead of the package main body 11 made of a metal. A second difference is that a circular metal member 15 attached via brazing to a top surface of an outer periphery wall of the package main body 21 is seam-welded to the lid 12. A third difference is that the polyurethane 13 is attached to an inner periphery side wall of the metal member 15. In terms of efficiency in adsorbing a foreign matter and efficiency in absorbing moisture, the polyurethane 13 is preferably attached to the metal member 15 so as to extend fully along the inner side surface 21a of the package main body 21.

### (Method for Producing Optical Element Modules 104 and 105)

Initially, the optical element 1 is mounted on the bottom surface 11b (21b) of the package main body 11 (21), and the polyurethane 13 is attached to a position of the package main body 11 which position is near a portion at which the package main body 11 is sealed with the lid 12, or to a position of the package main body 21 which position is near a portion at which the metal member 15 is sealed with the lid 12 (molded article-attaching step).

Then, as described in Embodiment 1, the polyurethane 13 is dried by vacuum-heating in the vacuum-heating step (drying step), and while the polyurethane 13 is kept in a dried state, the lid 12 with the window 12a is put on the opening of the package main body 11 so that the package main body 11 is sealed (sealing step).

The optical element module 104 illustrated in FIG. 4 and the optical element module 105 illustrated in FIG. 5 are produced through the aforementioned steps.

In production of the optical element module 104 illustrated in FIG. 4 and the optical element module 105 illustrated in FIG. 5, it is preferable to attach the polyurethane 13 in such a manner that a minute gap is provided between the polyurethane 13 and the lid 12 in consideration of a case where positioning is made by adjusting the position of the lid 12.

### (Effect)

According to the optical element modules 104 and 105 with the above configurations, it is possible to cause the polyurethane 13 to more effectively adsorb a foreign matter produced at portions to be seam-welded, e.g. a foreign matter produced by the lid 12 moving and consequently scraping the metal of the package main body 11 (or the metal member 15 of the package main body 21) in the step of putting the lid 12 on the package main body 11 (21), or in the step of adjusting the position of the lid 12, or during a standby time before seam-welding, or during transfer of the package main body 11 (21) on which the lid 12 is put before seam-welding.

For example, in a case where an uncured resin material which will have adherence after being cured is used as an adsorbing member other than the polyurethane 13, there is a possibility that a part of the resin material expands to and wet the portions to be seam-welded, thereby having an adverse influence on welding. In contrast, in the present invention, at a portion on the inner side surface 11a (21a) of the package main body 11 (21) which portion is near portions to be seam-welded, the polyurethane 13 having been molded to have a desired shape is used as an adsorbing member for adsorbing a foreign matter, and so the above problem does not occur.

In the optical element module 104 having the above configuration, the polyurethane 13 may be attached to a portion other than a portion near a portion to be seam-welded, e.g. a portion of the inner side surface 11a of the package main body 11 illustrated in FIG. 1 in accordance with Embodiment 1 above. In the optical element module 105 having the above configuration, the polyurethane 13 may be attached to a portion other than a portion near a portion to be seam-welded, e.g. a portion of the inner side surface 11a of the package main body 11 illustrated in FIG. 3 in accordance with Embodiment 2 above.

In Embodiments 1 through 3 above, a description was made as to a case where the resin molded article having self-adherence is polyurethane in a sheet form. However, the present invention is not limited to this, and polyurethane in a block form may be used instead.

### [Summary]

It is preferable to arrange the optical element module in accordance with the present Embodiment such that the resin molded article is attached to an inner side surface of the housing.

It is preferable to arrange the optical element module in accordance with the present Embodiment so as to further comprise a lid with an optically transmissive section for transmitting light, the resin molded article being attached to a portion of the housing and/or the lid, the portion not being directly irradiated with light having passed through the optically transmissive section.

With the arrangement, the resin molded article is attached to a portion in the optical element module which portion is not directly irradiated with light having passed through the optically transmissive section. Accordingly, external light is not directly incident to the resin molded article. Accordingly, even if the resin molded article is made of a material which will be deteriorated by light, it is possible to subdue deterioration of the resin molded article by light. In particular, in a case where the resin molded article is made of polyurethane, there is a concern of deterioration by ultraviolet ray, and accordingly irradiation of polyurethane with ultraviolet ray is preferably as small as possible.

It is preferable to arrange the optical element module in accordance with the present Embodiment such that the optical element is supported at a predetermined height above the bottom surface in the housing, and the resin molded article is attached to a portion of the bottom surface which portion faces the optical element.

With the arrangement, an upper side of the resin molded article, i.e. a side of the resin molded article which side is closer to the lid, is covered with the optical element. Accordingly, the light incident via the optically transmissive section of the lid is difficult to be directly incident to the resin molded article. Therefore, even if the resin molded article is made of a material which will be deteriorated by light, it is possible to subdue deterioration of the resin molded article by light.

It is preferable to arrange the optical element module in accordance with the present Embodiment such that the resin molded article is attached to a surface of the optical element which surface faces the bottom surface, as well as being attached to the aforementioned portion.

With the arrangement, by attaching the resin molded article to the surface of the optical element which surface faces the bottom surface, the light incident via the optically transmissive section of the lid is not directly incident to the resin molded article because the light is blocked by the optical element. This makes it possible to subdue deterioration of the resin molded article by light, as described above.

It is preferable to arrange the optical element module in accordance with the present Embodiment so as to contain an inert gas in a dried state. This makes it possible to reduce an amount of oxygen remaining, if any, in the optical element module. Accordingly, it is possible to reduce inconvenience caused by oxygen, such as an adverse influence on the resin molded article. In particular, in a case where the resin molded article is made of urethane, there is a concern of deterioration of the resin molded article by oxygen, and accordingly the amount of oxygen in the package is preferably as small as possible.

It is preferable to arrange the optical element module in accordance with the present Embodiment such that the inert gas is nitrogen.

It is preferable to arrange the optical element module in accordance with the present Embodiment such that the inert gas is a mixture gas of nitrogen and helium, and helium occupies 1-20% by volume of the mixture gas. In this arrangement, it is possible to detect leakage of a gas at a portion where the housing contacts the lid by sensing helium. In consideration of accuracy in sensing helium, an amount of helium to be mixed with nitrogen is 5-20% by volume with respect to an amount of the mixture gas of nitrogen and helium.

It is preferable to arrange the optical element module in accordance with the present Embodiment such that a dew point of the inert gas is no greater than a lower one of a temperature of an environment in which said optical element module is used and a temperature at which said optical element module is stored.

With the arrangement, when the dew point of the inert gas contained in the optical element module meets the above temperature condition, it is possible to prevent condensation in the optical element module. This makes it possible to eliminate an adverse influence caused by attachment of water droplets on the optical element and the resin molded article.

It is preferable to arrange the optical element module in accordance with the present Embodiment such that the resin molded article is made of a polyurethane resin material.

With the arrangement, since the polyurethane resin itself has adherence (self-adherence), the resin molded article can have high self-adherence after the resin molded article has been made of the polyurethane resin. Therefore, the resin molded article made of the polyurethane resin has high performance in adsorbing a foreign matter. Besides, the resin molded article is easy to be molded to have a desired volume and shape.

The resin molded article may be made of a resin material having self-adherence other than the polyurethane resin material.

### [Additional Matter]

The present invention is not limited to the embodiments, but can be altered by a skilled person in the art within the scope of the claims. An embodiment derived from a proper combination of technical means each disclosed in a different embodiment is also encompassed in the technical scope of the present invention.

### REFERENCE SIGNS LIST

1 Optical element
1a Rear surface
11 Package main body (housing)
11a Inner side surface
11b Bottom surface
12 Lid
13 Polyurethane (resin molded article)
14 Seat
15 Metal member
21 Package main body
21a Inner side surface
21b Bottom surface
101-105 Optical element module

1. An optical element module comprising a sealed housing and an optical element mounted in the sealed housing,
said optical element module further comprising a resin molded article having self-adherence and a desired shape, the resin molded article being fixed inside said optical element module with use of the self-adherence of the resin molded article.

2. The optical element module as set forth in claim 1, wherein the resin molded article is attached to an inner side surface of the housing.

3. The optical element module as set forth in claim 1, further comprising a lid with an optically transmissive section for transmitting light,
the resin molded article being attached to a portion of the housing and/or the lid, the portion not being directly irradiated with light having passed through the optically transmissive section.

4. The optical element module as set forth in claim 3, wherein
the optical element is supported at a predetermined height above the bottom surface in the housing, and
the resin molded article is attached to a portion of the bottom surface which portion faces the optical element.

5. The optical element module as set forth in claim 4, wherein the resin molded article is attached to a surface of the optical element which surface faces the bottom surface.

6. The optical element module as set forth in claim 1, containing an inert gas in a dried state.

7. The optical element module as set forth in claim 6, wherein the inert gas is nitrogen.

8. The optical element module as set forth in claim 6, wherein the inert gas is a mixture gas of nitrogen and helium, and helium occupies 1-20% by volume of the mixture gas.

9. The optical element module as set forth in claim 6, wherein a dew point of the inert gas is no greater than a lower one of a temperature of an environment in which said optical element module is used and a temperature at which said optical element module is stored.

10. The optical element module as set forth in claim 1, wherein the resin molded article is made of a polyurethane resin material.

11. A method for producing an optical element module including a sealed housing and an optical element mounted in the sealed housing,
said method comprising the steps of:
attaching a resin molded article having self-adherence and a desired shape to at least the housing with use of the self-adherence of the resin molded article;
vacuum-heating the housing on which the optical element has been mounted and to which the resin molded article has been attached; and thereafter
attaching a lid with an optically transmissive section for transmitting light to the housing and sealing the housing and the lid.

12. A method for producing an optical element module including a sealed housing and an optical element mounted in the sealed housing, the optical element module further including a lid with an optically transmissive section for transmitting light,
said method comprising the steps of:
attaching a resin molded article having self-adherence and a desired shape to a portion in the housing which portion is near a portion at which the housing and the lid are to be sealed; and
sealing the housing to which the resin molded article have been attached and the lid.
